(19) United States
(12) Patent Application Publication
(10) Pub. No.: US 2026/0342042 A1
(43) Pub. Date: Oct. 29, 2026

(54) LIGHT SOURCE DEVICE AND DISTANCE MEASUREMENT DEVICE

(71) Applicant: SONY SEMICONDUCTOR SOLUTIONS CORPORATION, KANAGAWA (JP)

(72) Inventors: TAKASHI MASUDA, KANAGAWA (JP); DAISUKE SUZUKI, KANAGAWA (JP); KOUTA HIYAMA, KANAGAWA (JP); TAKU OHSAWA, KANAGAWA (JP)

(21) Appl. No.: 19/103,603

(22) PCT Filed: Aug. 14, 2023
(86) PCT No.: PCT/JP2023/029426

§ 371 Date: Feb. 13, 2025

(30) Foreign Application Priority Data
Aug. 22, 2022 (JP) 2022-132014

(51) Int. Cl. H01S 5/042; G01S 7/484

(52) U.S. Cl. CPC H01S 5/0428; G01S 7/484

(57) ABSTRACT

A change in a light quantity due to a change in a light emission current of a light emitting element is reduced. A light source device includes: a plurality of light emitting elements; a plurality of switch elements that is respectively connected in series with respect to the plurality of light emitting elements and that causes a light emission current to flow during a light emission period; a light emission control unit that controls light emission of the plurality of light emitting elements by controlling the plurality of switch elements; a plurality of current limiting elements that is respectively arranged for the plurality of light emitting elements and that limits a current flowing through the light emitting elements to the light emitting current; a light emission current control unit that supplies a current control signal corresponding to the light emission current to control terminals of the plurality of current limiting elements; and a light emission current adjustment unit that adjusts the light emission current according to the number of light emitting elements caused to emit light among the plurality of light emitting elements.

### FIELD

The present disclosure relates to a light source device and a distance measurement device using the light source device.

### BACKGROUND

A light source device including a plurality of light emitting elements arranged in an array is used. For example, a light source device using laser diodes as the light emitting elements is used. A light source device with a high light quantity can be formed by arrangement of high-output laser diodes in an array. In such a light source device, a light source device in which a driving transistor that supplies a constant current for driving is arranged for each light emitting element has been proposed (see, for example, Patent Literature 1.).

In this light source device, a constant light emission current (drive current) is supplied to each driving transistor by a current mirror circuit. That is, each of the driving transistors, and a MOS transistor that configures the current mirror circuit are arranged, and a reference current of the MOS transistor is mirrored to each of the drive transistors and supplied as the light emission current.

### CITATION LIST

### Patent Literature

Patent Literature 1: Japanese Patent Application Laid-Open No. 2020-043229

### SUMMARY

### Technical Problem

However, in the above-described conventional technology, there is a problem that source potential of the driving transistors changes and the light emission currents vary in a case where the light emission currents of the plurality of light emitting elements flow through common impedance of wiring lines on a source side of the driving transistors. This causes a problem that the light quantity of the light source device varies.

Thus, the present disclosure proposes a light source device and a distance measurement device that reduce a change in a light quantity due to a change in a light emission current of a light emitting element.

### Solution to Problem

A light source device according to the present disclosure includes: a plurality of light emitting elements; a plurality of switch elements that is respectively connected in series with respect to the plurality of light emitting elements and that causes a light emission current to flow during a light emission period; a light emission control unit that controls light emission of the plurality of light emitting elements by controlling the plurality of switch elements; a plurality of current limiting elements that is arranged respectively for the plurality of light emitting elements and that limits a current flowing through the light emitting elements to the light emitting current; a light emission current control unit that supplies a current control signal corresponding to the light emission current to control terminals of the plurality of current limiting elements; and a light emission current adjustment unit that adjusts the light emission current according to the number of light emitting elements caused to emit light among the plurality of light emitting elements.

A distance measurement device according to the present disclosure includes: a light source device including a plurality of light emitting elements, a plurality of switch elements that is respectively connected in series with respect to the plurality of light emitting elements and that causes a light emission current to flow during a light emission period, a light emission control unit that controls light emission of the plurality of light emitting elements by controlling the plurality of switch elements, a plurality of current limiting elements that is respectively arranged for the plurality of light emitting elements and limits a current flowing through the light emitting elements to the light emission current, a light emission current control unit that supplies a current control signal corresponding to the light emission current to control terminals of the plurality of current limiting elements, and a light emission current adjustment unit that adjusts the light emission current according to number of light emitting elements caused to emit light among the plurality of light emitting elements; a photodetection element that detects reflected light that is light emitted from the light source device and reflected by an object; and a distance measurement unit that measures a distance to the object by measuring time from emission of the light to detection of the reflected light.

### BRIEF DESCRIPTION OF DRAWINGS

FIG. 1 is a view illustrating a configuration example of a light source device according to a first embodiment of the present disclosure.

FIG. 2 is a view for describing a variation of a light emission current according to an embodiment of the present disclosure.

FIG. 3 is a view illustrating a configuration example of a light emission current adjustment unit according to the first embodiment of the present disclosure.

FIG. 4 is a view illustrating an example of an adjustment current according to the first embodiment of the present disclosure.

FIG. 5 is a view illustrating a configuration example of a light source device according to a second embodiment of the present disclosure.

FIG. 6 is a view illustrating an example of an adjustment current according to the second embodiment of the present disclosure.

FIG. 7 is a view illustrating another example of an adjustment current according to the second embodiment of the present disclosure.

FIG. 8A is a view illustrating an example of a region according to the second embodiment of the present disclosure.

FIG. 8B is a view illustrating an example of a region according to the second embodiment of the present disclosure.

FIG. 8C is a view illustrating an example of a region according to the second embodiment of the present disclosure.

FIG. 9 is a view illustrating a configuration example of a light source device according to a third embodiment of the present disclosure.

FIG. 10 is a view illustrating an example of an adjustment current according to the third embodiment of the present disclosure.

FIG. 11 is a view illustrating a configuration example of a light source device according to a fourth embodiment of the present disclosure.

FIG. 12 is a view illustrating a configuration example of a light emission current adjustment unit according to the fourth embodiment of the present disclosure.

FIG. 13 is a view illustrating a configuration example of a light emission control unit according to the fourth embodiment of the present disclosure.

FIG. 14A is a view illustrating a configuration example of a light emission signal generation circuit according to the fourth embodiment of the present disclosure.

FIG. 14B is a view illustrating an example of generation of a light emission signal according to the fourth embodiment of the present disclosure.

FIG. 15 is a view illustrating a configuration example of a light source device according to a fifth embodiment of the present disclosure.

FIG. 16 is a view illustrating a configuration example of a light source device according to a first modification example of the embodiment of the present disclosure.

FIG. 17 is a view illustrating a configuration example of a light source device according to a second modification example of the embodiment of the present disclosure.

FIG. 18A is a view illustrating a configuration example of a light emitting element according to the embodiment of the present disclosure.

FIG. 18B is a view illustrating another configuration example of a light emitting element according to the embodiment of the present disclosure.

FIG. 19A is a view illustrating an example of light emission by a light emitting element according to the embodiment of the present disclosure.

FIG. 19B is a view illustrating an example of light emission by the light emitting element according to the embodiment of the present disclosure.

FIG. 20 is a view illustrating a configuration example of a distance measurement device to which a light source device according to the embodiment of the present disclosure can be applied.

### DESCRIPTION OF EMBODIMENTS

In the following, embodiments of the present disclosure will be described in detail on the basis of the drawings. The description will be made in the following order. Note that in each of the following embodiments, overlapped description is omitted by assignment of the same reference sign to the same parts.
1. First embodiment
2. Second embodiment
3. Third embodiment
4. Fourth embodiment
5. Fifth embodiment
6. Modification example
7. Configuration of a light emitting element
8. Application example to a distance measurement device

### 1. First Embodiment

### Configuration of a Light Source Device

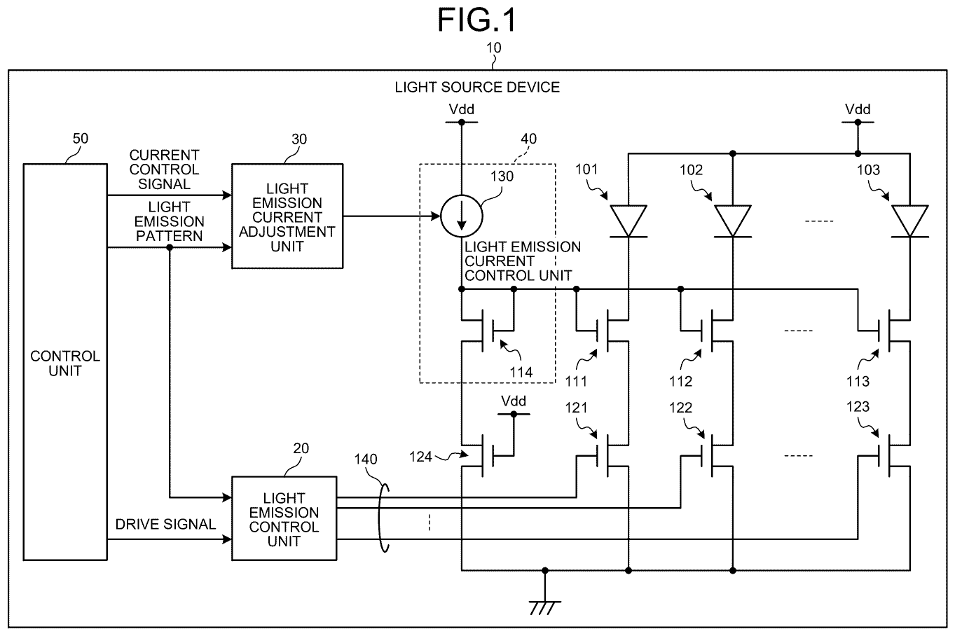

FIG. 1 is a view illustrating a configuration example of a light source device according to the first embodiment of the present disclosure. The drawing is a block diagram illustrating a configuration example of a light source device 10. The light source device 10 includes a plurality of (n) light emitting elements 101 to 103, a plurality of (n) switch elements 121 to 123, a plurality of (n) current limiting elements 111 to 113, a MOS transistor 124, and a light emission control unit 20. Furthermore, the light source device 10 further includes a light emission current adjustment unit 30, a light emission current control unit 40, and a control unit 50.

The light emitting elements 101 to 103 are semiconductor elements that emit light when a light emission current flows. For example, laser diodes can be used as the light emitting elements 101 and the like.

The switch elements 121 to 123 are elements that are respectively connected in series with respect to the plurality of light emitting elements 101 to 103 and cause the light emission current to flow during a light emission period. As the switch elements 121 to 123, n-channel MOS transistors can be used.

The current limiting elements 111 to 113 are elements that are respectively arranged for the plurality of light emitting elements 101 to 103 and limit the current flowing through the light emitting elements 101 to 103 to the light emission current. As the current limiting elements 111 to 113, n-channel MOS transistors can be used.

The light emission current control unit 40 supplies a current control signal corresponding to the light emission current to control terminals of the plurality of current limiting elements 111 to 113. Note that gates of the current limiting elements 111 to 113 correspond to the control terminals. The light emission current control unit 40 includes a constant current circuit 130 and a MOS transistor 114.

Connection of the circuit of the light source device 10 will be described. An anode of the light emitting element 101 is connected to a power supply line Vdd that supplies power, and a cathode of the light emitting element 101 is connected to a drain of the current limiting element 111. A source of the current limiting element 111 is connected to a drain of the switch element 121, and a source of the switch element 121 is grounded. In such a manner, the light emitting element 101, the current limiting element 111, and the switch element 121 connected in series are connected between the power supply line Vdd and a ground wire. The light emitting element 102, the current limiting element 112, and the switch element 122, and the light emitting element 103, the current limiting element 113, and the switch element 123 are similarly connected. Nodes of the light emitting element 101, the current limiting element 111, and the switch element 121 connected in series are hereinafter referred to as light emitting element nodes. n light emitting element nodes are arranged in the light source device 10. Note that gates of the switch elements 121 to 123 are connected to an output of the light emission current control unit 40.

A sink-side terminal of the constant current circuit 130 of the light emission current control unit 40 is connected to the power supply line Vdd, and a source-side terminal is connected to a drain and gate of the MOS transistor 114 and the gates of the current limiting elements 111 to 113. A source of the MOS transistor 114 is connected to a drain of the MOS transistor 124, and a source of the MOS transistor 124 is grounded. A gate of the MOS transistor 124 is connected to the power supply line Vdd.

As illustrated in the drawing, the MOS transistor 114 of the light emission current control unit 40 and the current limiting elements 111 to 113 are included in the current mirror circuit. That is, a reference current that is a current flowing through the MOS transistor 114 is mirrored to the current limiting elements 111 to 113. Note that the MOS transistor 124 is an element connected to acquire a voltage drop corresponding to the switch element 121. Thus, a mirror ratio of the current mirror circuit is 1:1. For example, when the switch elements 121 to 123 are conducted, sources of the current limiting elements 111 to 113 and the ground wire are substantially short-circuited. Thus, a current equal to the reference current of the constant current circuit 130 flows through each of the current limiting elements 111 to 113. This current becomes a light emission current.

By selecting and conducting the switch elements 121 to 123, it is possible to cause a desired light emitting element to emit light. Note that the reference current of the constant current circuit 130 is controlled by the light emission current adjustment unit 30 described later.

Note that the light source device 10 in the drawing represents an example in which the light emitting elements 101 to 103 and the light emission current control unit 40 are connected to the same power supply (power supply line Vdd). However, the circuit configuration of the light emitting element 101 and the like is not limited to this example. For example, different power supplies (circuits) can be connected to the light emitting elements 101 to 103 and the light emission current control unit 40. At this time, it is also possible to supply power with different voltages in the light emitting elements 101 to 103 and the light emission current control unit 40. Furthermore, the mirror ratio of the current mirror circuit including the MOS transistor 114 of the light emission current control unit 40 and the current limiting elements 111 to 113 can be set to different values. For example, it is possible to set the mirror ratio to 1:N by setting an aspect ratio of the current limiting elements 111 to 113 to the MOS transistor 114 to N times. As a result, power consumption of the light emission current control unit 40 and the like can be reduced. Note that in this case, the aspect ratio of the switch elements 121 to 123 to the MOS transistor 124 also needs to be N times.

The light emission control unit 20 controls light emission of the plurality of light emitting elements 101 to 103 by controlling the plurality of switch elements 121 to 123. The light emission control unit 20 individually conducts and controls the switch elements 121 to 123. The light emission control unit 20 outputs an ON signal of the MOS transistors included in the switch elements 121 to 123. The ON signal is a signal having a voltage equal to or higher than a gate-source voltage Vgs that brings the MOS transistors into a conductive state. The switch element 121 or the like to the gate of which the ON signal is applied is brought into a conductive state.

A drive signal and a light emission pattern are input to the light emission control unit 20. The drive signal is a signal indicating timing at which the light emitting elements 101 to 103 are caused to emit light, and is a signal indicating timing at which the switch elements 121 to 123 are brought into the conductive state. Furthermore, the light emission pattern is a signal indicating a light emitting element caused to emit light among the light emitting elements 101 to 103. The light emission control unit 20 selects the switch elements 121 to 123 on the basis of the light emission pattern, and outputs the ON signal to the selected switch elements 121 to 123 at timing based on the drive signal.

The light emission current adjustment unit 30 controls the light emission current of the light emission current control unit 40. Specifically, the light emission current adjustment unit 30 performs control to cause the reference current corresponding to the light emission current to flow in the constant current circuit 130 of the light emission current control unit 40. Furthermore, the light emission current adjustment unit 30 further adjusts the light emission current corresponding to the number of light emitting elements caused to emit light among the plurality of light emitting elements 101 to 103. As described later, in the current limiting elements 111 to 113 included in the current mirror circuit, the light emission current changes according to the number of light emitting elements. The light emission current adjustment unit 30 adjusts the light emission current in order to compensate for the change in the light emission current. Details of the configuration of the light emission current adjustment unit 30 will be described later.

The control unit 50 controls the entire light source device 10. The control unit 50 generates the current control signal, the light emission pattern, and the drive signal on the basis of an instruction from an external device, and performs an output thereof to the light emission current adjustment unit 30 and the light emission control unit 20.

### Variation of a Light Emission Current

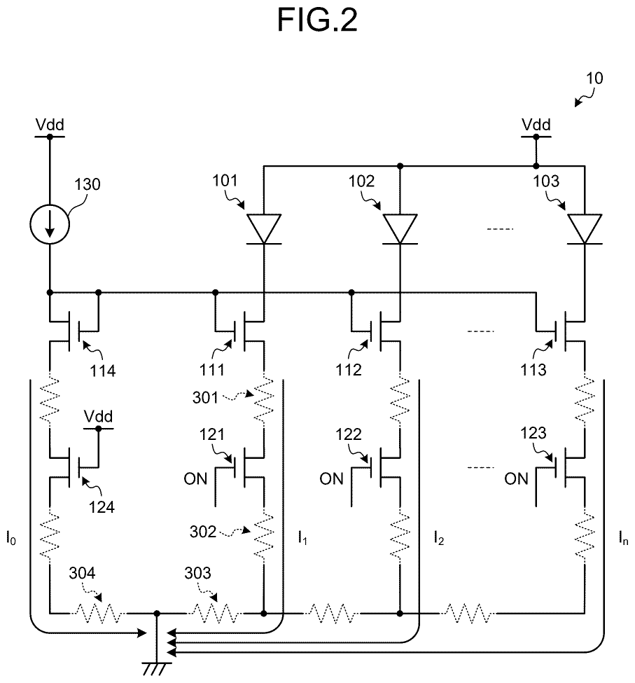

FIG. 2 is a view for describing the variation of the light emission current according to the embodiment of the present disclosure. The drawing is a view illustrating circuit portions of the light emitting elements 101 to 103 in FIG. 1. In the drawing, I₀ represents the current (reference current) of the MOS transistor 114. Furthermore, I₁ to Iₙ represent the light emission currents of the current limiting elements 111 to 113. Furthermore, parasitic resistance of the source-side wiring lines of the MOS transistor 114 and the current limiting elements 111 to 113 included in the current mirror circuit is illustrated in the drawing. Resistors indicated by broken lines in the drawing correspond to the parasitic resistance. Normally, parasitic resistance based on wiring resistance exists in a wiring line. Thus, when a current flows through the wiring line, a voltage drop is generated. In a case where the parasitic resistance varies between the MOS transistor 114 and the current limiting elements 111 to 113, the source voltage of the MOS transistor 114 or the like changes, the mirror ratio changes, and variations are generated in the light emission currents I₁ to Iₙ.

When the current limiting element 111 is described as an example, parasitic resistance 301 and 302 exists in the source-side wiring line of the current limiting element 111. In a case where the parasitic resistance 301 and 302 is different from the parasitic resistance of the MOS transistor 114, the effective gate-source voltages Vgs of the current limiting element 111 and the MOS transistor 114 are different. Thus, the light emission current I₁ of the current limiting element 111 has a value different from the current I₀ of the current limiting element 111.

In addition, parasitic resistance also exists in the ground wire. In the parasitic resistance, parasitic resistance through which a plurality of light emission currents flows in common is referred to as common impedance. The parasitic resistance 303 in the drawing corresponds to common impedance through which the light emission currents I₁ to Iₙ flow. The voltage drop of the parasitic resistance 303 that becomes the common impedance is changed by the flowing light emission currents. That is, the voltage drop of the parasitic resistance 303 varies depending on the number of light emitting elements among the light emitting elements 101 to 103. Thus, in the current limiting element 111 in which the light emission current I₁ flows through the parasitic resistance 303, the effective gate-source voltage Vgs changes due to the light emission current from another light emitting element node, and the light emission current varies.

Specifically, when only the light emitting element 101 is caused to emit light, only the light emission current I₁ flows through the parasitic resistance 303. Thus, the voltage drop of the parasitic resistance 303 is substantially equal to the voltage drop of the parasitic resistance 304 of the ground wire in the MOS transistor 114. Thus, the light emission current I₁ of the light emitting element 101 becomes a current substantially equal to I₀. On the other hand, in a case where all of the light emitting elements 101 to 103 emit light, the voltage drop of the parasitic resistance 303 increases and the effective gate-source voltage Vgs decreases. Thus, the light emission current I₁ decreases below I₀. In such a manner, the light emission current changes according to the number of light emitting elements among the light emitting elements 101 to 103. The light emission current adjustment unit 30 performs an operation of compensating for the change in the light emission current.

### Configuration of a Light Emission Current Adjustment Unit

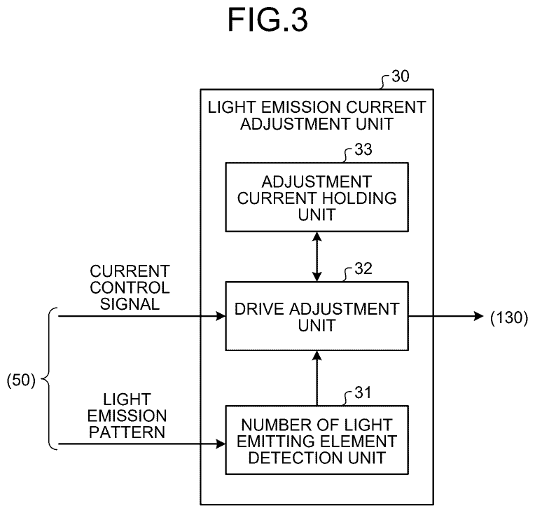

FIG. 3 is a view illustrating a configuration example of the light emission current adjustment unit according to the first embodiment of the present disclosure. The drawing is a block diagram illustrating a configuration example of the light emission current adjustment unit 30. The light emission current adjustment unit 30 in the drawing includes a number of light emitting element detection unit 31, a drive adjustment unit 32, and an adjustment current holding unit 33.

The number of light emitting element detection unit 31 detects the number of light emitting elements on the basis of the light emission pattern. The number of light emitting element detection unit 31 outputs the number of light emitting elements to the drive adjustment unit 32.

The drive adjustment unit 32 performs control to cause the reference current to flow through the constant current circuit 130 of the light emission current adjustment unit 30 on the basis of the current control signal. Furthermore, the drive adjustment unit 32 further performs control of adjusting the reference current of the constant current circuit 130 on the basis of the number of light emitting elements from the number of light emitting element detection unit 31. The drive adjustment unit 32 adjusts the reference current on the basis of the adjustment current of the adjustment current holding unit 33.

The adjustment current holding unit 33 holds information of adjustment current for adjusting the reference current. The adjustment current holding unit 33 includes a table representing correspondence between the number of light emitting elements and the adjustment current.

### Adjustment Current

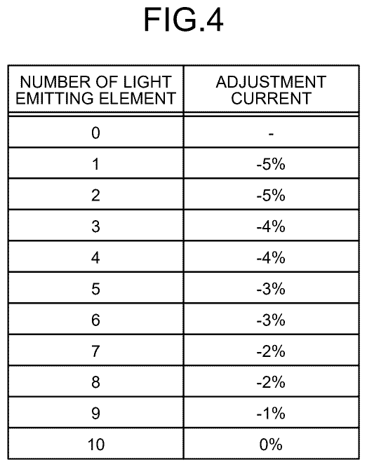

FIG. 4 is a view illustrating an example of the adjustment current according to the first embodiment of the present disclosure. The drawing is a view illustrating an example of the adjustment current held in the adjustment current holding unit 33. The number of light emitting elements in the drawing represents the number of light emitting elements among the light emitting elements 101 to 103. A case where the number of light emitting elements (light emitting element nodes) is 10 is represented in the drawing. The adjustment current in the drawing represents an adjustment value of the light emission current. The adjustment current in the drawing represents an example in which the value increases as the number of light emitting elements decreases on the basis of a case where the number of light emitting elements is 10. Specifically, in a case where the number of light emitting elements is “1”, the adjustment current is “−5%”. In this case, the drive adjustment unit 32 performs adjustment to subtract 5% from the light emission current (reference current) of a case where the number of light emitting elements is “10”. The drive adjustment unit 32 controls the constant current circuit 130 in such a manner that the adjusted reference current flows. As a result, the value of the light emission current is adjusted according to the number of light emitting elements.

As described above, the light source device 10 of the first embodiment of the present disclosure adjusts the light emission currents of the light emitting elements 101 to 103 according to the number of light emitting elements. As a result, the variation in the light emission currents of the light emitting elements 101 to 103 can be reduced, and the variation in the light quantity of the light source device 10 can be reduced.

### 2. Second Embodiment

In the light source device 10 of the first embodiment described above, a plurality of light emitting elements is arranged. On the other hand, a light source device 10 of the second embodiment of the present disclosure is different from the above-described first embodiment in a point that a plurality of light emitting elements is divided into a plurality of regions.

### Configuration of a Light Source Device

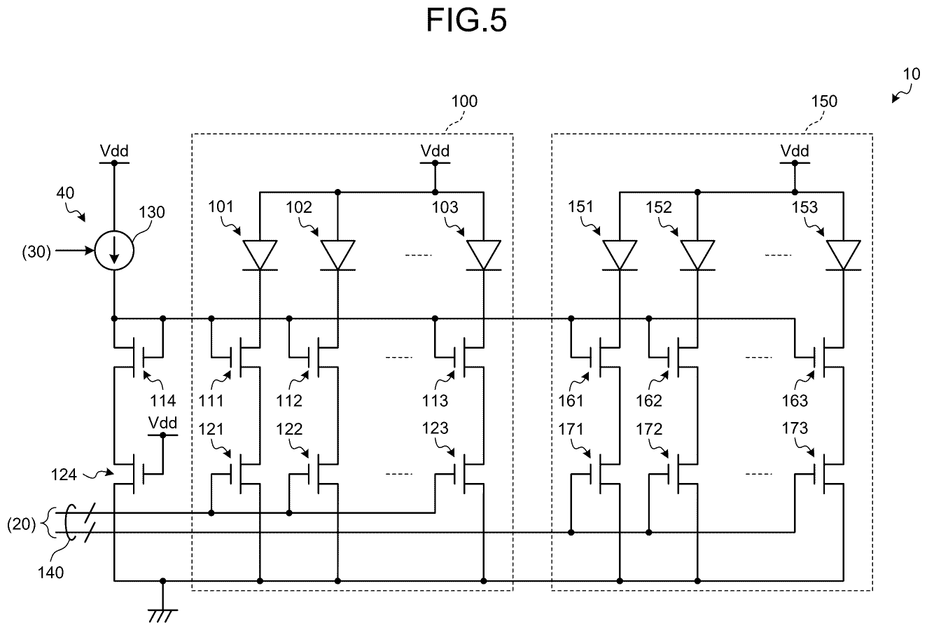

FIG. 5 is a view illustrating a configuration example of the light source device according to the second embodiment of the present disclosure. Similarly to FIG. 1, the drawing is a view illustrating a configuration example of the light source device 10. The light source device 10 in the drawing is different from the light source device 10 in FIG. 1 in a point that light emitting element nodes are divided into a plurality of regions.

The light source device 10 in the drawing includes a region 100 including light emitting element nodes of light emitting elements 101 to 103, and a region 150 including light emitting element nodes of light emitting elements 151 to 153. The region 150 includes the light emitting elements 151 to 153, current limiting elements 161 to 163, and switch elements 171 to 173. Each of the light emitting elements 151 to 153 configures a light emitting element node. Note that the region 150 in the drawing represents an example including the same number of light emitting element nodes as the region 100. Furthermore, the current limiting elements 161 to 163 in the region 150 and a MOS transistor 114 are included in a current mirror circuit. The configuration including such regions 100 and 150 is applied to a case where the plurality of light emitting elements 101 and the like are divided in hardware.

### Adjustment Current

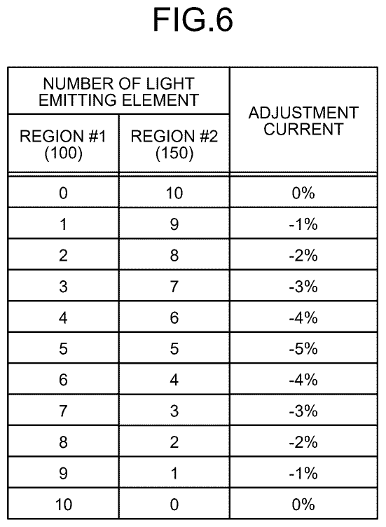

FIG. 6 is a view illustrating an example of an adjustment current according to the second embodiment of the present disclosure. Similarly to FIG. 4, the drawing is a view illustrating an example of the adjustment current held in an adjustment current holding unit 33. A “region #1” and a “region #2” in the drawing respectively indicate the numbers of light emitting elements in the regions 100 and 150. When the number of light emitting elements is “5” in the regions 100 and 150, an adjustment value is the smallest (absolute value is the largest).

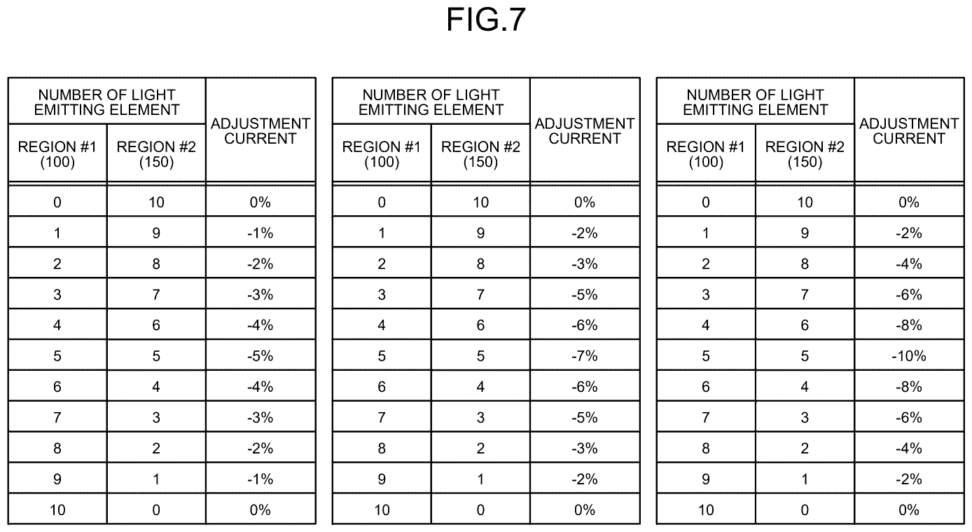

FIG. 7 is a view illustrating another example of the adjustment current according to the second embodiment of the present disclosure. Similarly to FIG. 6, the drawing is a view illustrating an example of the adjustment current held in the adjustment current holding unit 33. An example in which an adjustment value is changed according to a light emission current is illustrated in the drawing. The adjustment current at a left end of the drawing represents the adjustment current of a case where the light emission current is low (case of low light quantity). In addition, the adjustment current at a center of the drawing represents the adjustment current of a case of a middle light emission current. In addition, the adjustment current at a right end of the drawing represents the adjustment current of a case of a large light emission current (in a case of a high light quantity). As illustrated in the drawing, in a case where the light emission current is large, the adjustment value can be made large. This is because a voltage drop of parasitic resistance 303 that is common impedance increases.

### Configuration of a Region

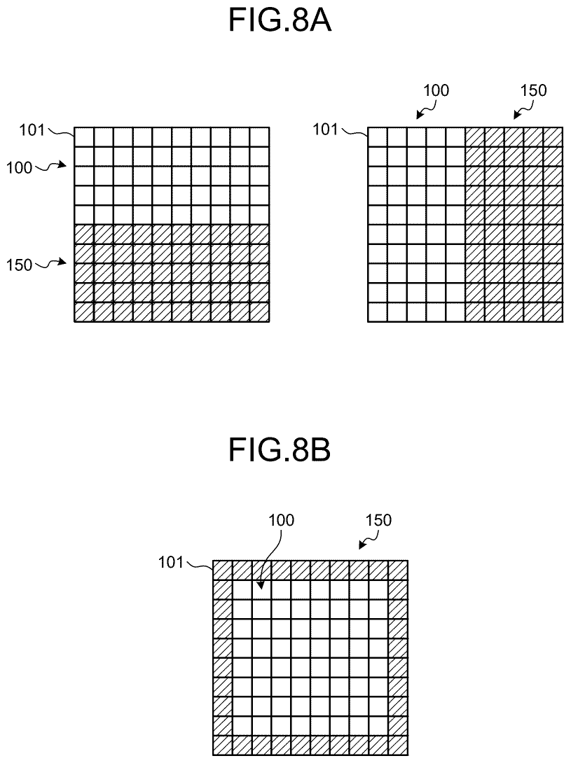

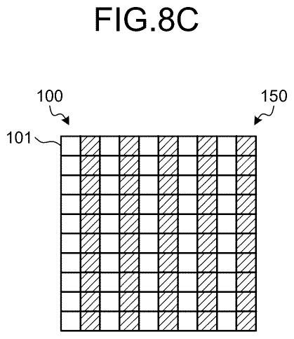

FIGS. 8A to 8C are views illustrating an example of a region according to the second embodiment of the present disclosure. Rectangles in the drawings represent the light emitting elements 101 and the like. In the drawing, the light emitting elements 101 and the like are arranged in a two-dimensional matrix. In addition, white rectangles in the drawing represent light emitting elements included in the region 100, and hatched rectangles represent light emitting elements included in the region 150.

FIG. 8A is a view illustrating an example in which the plurality of light emitting elements 101 and the like are equally divided into the rectangular regions 100 and 150.

FIG. 8B is a view illustrating an example in which light emitting elements on an outer periphery among the plurality of light emitting elements 101 and the like are arranged in the region 150, and light emitting elements on an inner side are arranged in the region 100.

FIG. 8C is a view illustrating an example in which the plurality of light emitting elements 101 and the like are alternately distributed to the regions 100 and 150 for each column.

Since the configuration of the light source device 10 other than the above is similar to the configuration of the light source device 10 in the first embodiment of the present disclosure, description thereof will be omitted.

As described above, in a case where the plurality of light emitting elements 101 and the like is divided into the plurality of regions 100 and the like, the light source device 10 of the second embodiment of the present disclosure adjusts light emission currents of the light emitting elements 101 to 103 and the like according to the number of light emitting elements.

### 3. Third Embodiment

In the light source device 10 of the second embodiment described above, the plurality of light emitting elements 101 and the like is divided into the regions 100 and 150. On the other hand, a light source device 10 of the third embodiment of the present disclosure is different from the above-described second embodiment in a point that a current mirror circuit of a current limiting element 161 or the like is configured for each divided region.

### Configuration of a Light Source Device

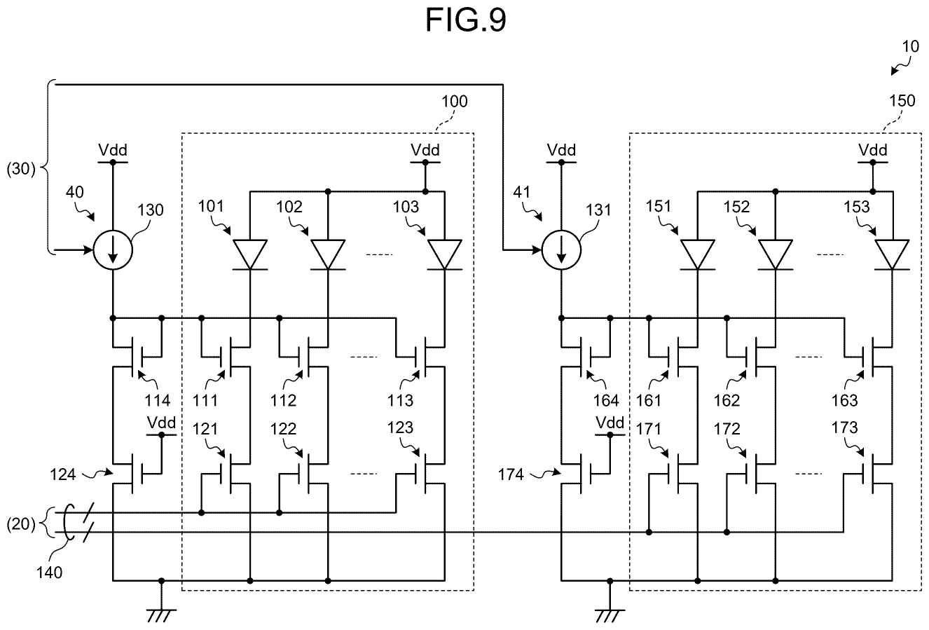

FIG. 9 is a view illustrating a configuration example of a light source device according to the third embodiment of the present disclosure. Similarly to FIG. 5, the drawing is a view illustrating a configuration example of the light source device 10. The light source device 10 in the drawing is different from the light source device 10 in FIG. 5 in a point that different current mirror circuits are arranged in the regions 100 and 150.

The light source device 10 in the drawing further includes a constant current circuit 131 and MOS transistors 164 and 174. Note that circuits of the constant current circuit 131 and the MOS transistor 164 are included in a light emission current control unit 41.

A sink-side terminal of the constant current circuit 131 of the light emission current control unit 41 is connected to the power supply line Vdd, and a source-side terminal is connected to a drain and gate of the MOS transistor 164 and gates of the current limiting elements 161 to 163. A source of the MOS transistor 164 is connected to a drain of a MOS transistor 174, and a source of the MOS transistor 174 is grounded. A gate of the MOS transistor 174 is connected to the power supply line Vdd.

In addition, a light emission current adjustment unit 30 (not illustrated) of the light source device 10 in the drawing adjusts the light emission currents of the plurality of light emission current control units 40 and 41.

### Adjustment Current

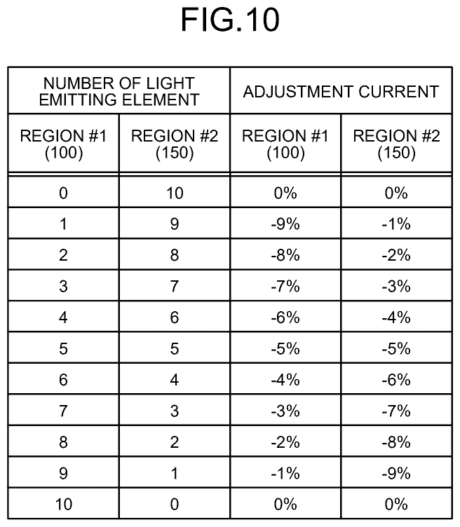

FIG. 10 is a view illustrating an example of an adjustment current according to the third embodiment of the present disclosure. Similarly to FIG. 6, the drawing is a view illustrating an example of the adjustment current held in an adjustment current holding unit 33. As illustrated in the drawing, the adjustment current holding unit 33 according to the third embodiment of the present disclosure holds the adjustment current for each of the regions 100 and 150. On the basis of the adjustment current for each of the regions 100 and 150, the light emission current adjustment unit 30 can adjust the light emission current for each of the regions 100 and 150. For example, as in the regions 100 and 150 in FIG. 8B, even in a case where arrangements of parasitic resistance that is common impedance vary greatly between the regions, the light emission current can be compensated for each of the regions 100 and 150.

Since the configuration of the optical device 10 other than the above is similar to the configuration of the light source device 10 in the second embodiment of the present disclosure, description thereof will be omitted.

As described above, the light source device 10 of the third embodiment of the present disclosure includes the light emission current control units 40 and 41 respectively for the regions 100 and 150. As a result, a variation of the light emission current can be further reduced.

### 4. Fourth Embodiment

The light source device 10 of the above-described first embodiment adjusts the light emission current by adjusting a value of the light emission current. On the other hand, a light source device 10 of the fourth embodiment of the present disclosure is different from that of the above-described first embodiment in a point that a light emission current is adjusted by an adjustment of a period during which the light emission current flows.

### Configuration of a Light Source Device

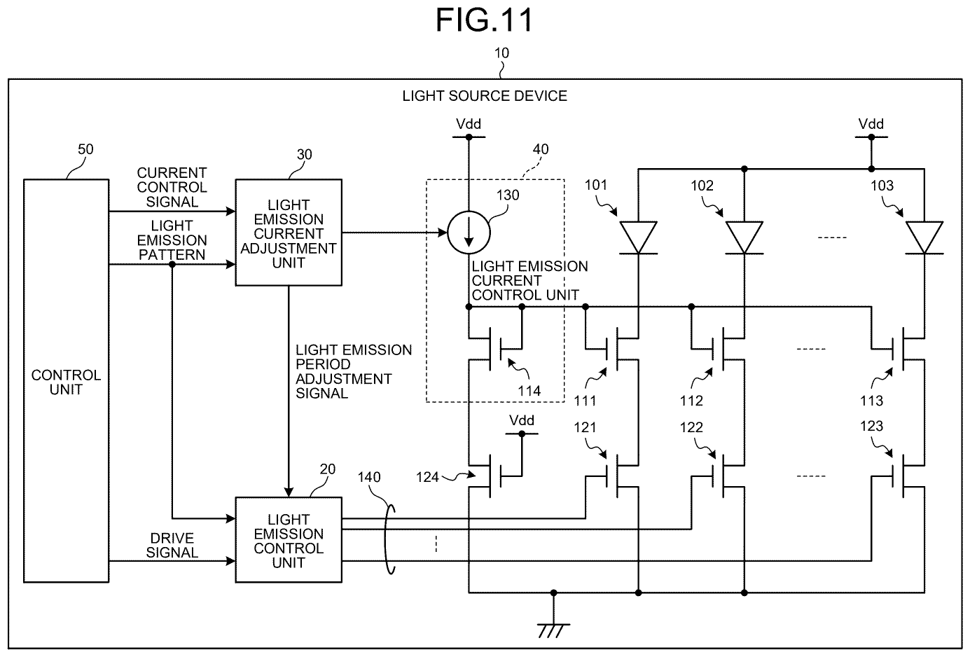

FIG. 11 is a view illustrating a configuration example of a light source device according to the fourth embodiment of the present disclosure. Similarly to FIG. 1, the drawing is a view illustrating a configuration example of the light source device 10. The light source device 10 in the drawing is different from the light source device 10 in FIG. 1 in a point that a light emission control unit 20 adjusts a light emission period of a light emitting element 101 or the like on the basis of a light emission period adjustment signal output from a light emission current adjustment unit 30.

The light emission current adjustment unit 30 in the drawing does not need to adjust a light emission current (reference current) of a light emission current control unit 40. Instead, the light emission current adjustment unit 30 in the drawing outputs the light emission period adjustment signal to the light emission control unit 20. The light emission period adjustment signal is a signal for adjusting the light emission period according to the number of light emitting elements.

The light emission control unit 20 in the drawing outputs, to switch elements 121 to 123, a bulse-like ON signal in which the light emission period is adjusted on the basis of the light emission period adjustment signal.

### Configuration of a Light Emission Current Adjustment Unit

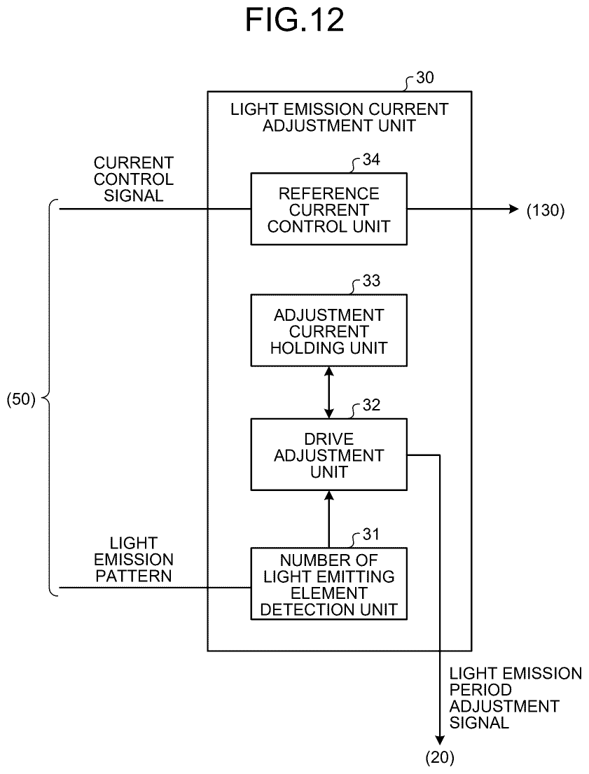

FIG. 12 is a view illustrating a configuration example of the light emission current adjustment unit according to the fourth embodiment of the present disclosure. Similarly to FIG. 3, the drawing is a block diagram illustrating a configuration example of the light emission current adjustment unit 30. The light emission current adjustment unit 30 in the drawing is different from the light emission current adjustment unit 30 in FIG. 3 in a point that a reference current control unit 34 is further included and a drive adjustment unit 32 generates and outputs the light emission period adjustment signal.

The reference current control unit 34 performs control to cause the reference current to flow through a constant current circuit 130 of the light emission current control unit 40 on the basis of a current control signal.

The drive adjustment unit 32 in the drawing generates the light emission period adjustment signal on the basis of the number of light emitting elements from a number of light emitting element detection unit 31. The light emission period adjustment signal is input to a delay circuit 221 of a light emission signal generation circuit 22 of the light emission control unit 20 described later. The light emission period adjustment signal is a signal indicating a delay time of the delay circuit 221.

### Configuration of a Light Emission Control Unit

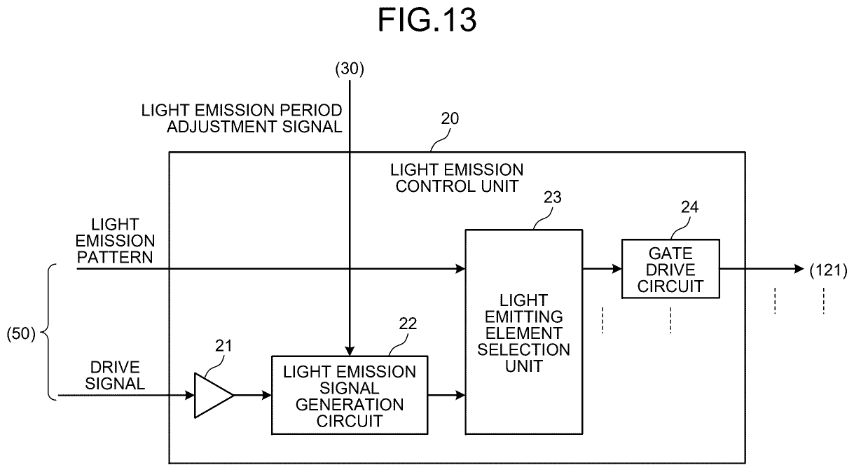

FIG. 13 is a view illustrating a configuration example of the light emission control unit according to the fourth embodiment of the present disclosure. The drawing is a block diagram illustrating a configuration example of the light emission control unit 20. The light emission control unit 20 in the drawing includes a non-inversion buffer 21, a light emission signal generation circuit 22, a light emitting element selection unit 23, and a plurality of gate drive circuits 24.

The non-inversion buffer 21 corresponds to a buffer amplifier, amplifies a drive signal, and performs an output thereof to the light emission signal generation circuit 22.

The light emission signal generation circuit 22 is a circuit that generates a pulsed light emission signal on the basis of a drive signal input via the non-inversion buffer 21. Furthermore, the light emission signal generation circuit 22 further adjusts a hulse width of the light emission signal on the basis of the light emission period adjustment signal from the light emission current adjustment unit 30. Details of the configuration of the light emission signal generation circuit 22 will be described later.

The light emitting element selection unit 23 selects the light emitting element 101 or the like caused to emit light on the basis of a light emission pattern, and outputs the light emission signal to a light emitting element node of the selected light emitting element 101 or the like.

The gate drive circuit 24 is arranged for each light emitting element node, and generates and outputs a pulsed ON signal on the basis of the light emission signal from the light emitting element selection unit 23.

### Configuration of a Light Emission Signal Generation Circuit

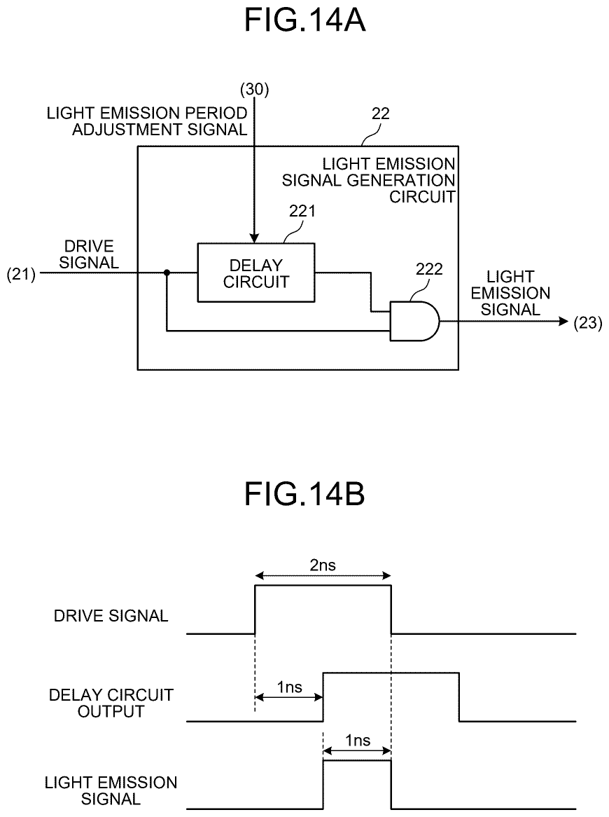

FIG. 14A is a view illustrating a configuration example of the light emission signal generation circuit according to the fourth embodiment of the present disclosure. The drawing is a block diagram illustrating a configuration example of the light emission signal generation circuit 22. The light emission signal generation circuit 22 in the drawing includes the delay circuit 221 and an AND gate 222.

The delay circuit 221 is a circuit that delays the drive signal on the basis of the light emission period adjustment signal. The AND gate 222 is a gate that performs an AND operation of the drive signal and the drive signal delayed by the delay circuit 221. An output of the AND gate 222 corresponds to the light emission signal.

### Generation of a Light Emission Signal

FIG. 14B is a view illustrating an example of generation of the light emission signal according to the fourth embodiment of the present disclosure. A “drive signal” in the drawing represents a waveform of the drive signal. In addition, a “delay circuit output” in the drawing represents a waveform of an output signal of the delay circuit 221. In addition, a “light emission signal” in the drawing represents a waveform of a light emission signal that is an output signal of the AND gate 222.

In the drawing, a signal having a pulse width of 2 ns is assumed as the drive signal. Furthermore, the waveform of the delay circuit output in the drawing represents an example in which the delay circuit 221 delays the drive signal by 1 ns. The light emission signal can be generated by the AND operation on these two signal waveforms. As illustrated in the drawing, this light emission signal is a signal in which a bulse width changes according to the delay time of the delay circuit 221.

The light emission current adjustment unit 30 of the fourth embodiment of the present disclosure outputs the light emission period adjustment signal corresponding to the number of light emitting elements. The light emission period adjustment signal is, for example, a signal instructing a delay time in which a pulse width corresponding to the adjustment value illustrated in FIG. 4 is acquired. The light emission period adjustment signal is input to the delay circuit 221, and the pulse width of the light emission signal is adjusted. For example, in a case where the number of light emitting elements is “1”, adjustment to reduce the pulse width of the light emission signal by 5% is performed. As a result, the sum (integrated value) of light quantity of the light source device 10 in the light emission period can be leveled.

Since the configuration of the light source device 10 other than the above is similar to the configuration of the light source device 10 in the first embodiment of the present disclosure, description thereof will be omitted.

As described above, the light source device 10 of the fourth embodiment of the present disclosure adjusts the light emission period according to the number of light emitting elements of the light emitting elements 101 and the like. This makes it possible to reduce a change in the total amount of the light quantity in the light emission period.

### 5. Fifth Embodiment

An example in which an overcurrent detection unit is added to the light source device 10 of the above-described first embodiment will be described.

### Configuration of a Light Source Device

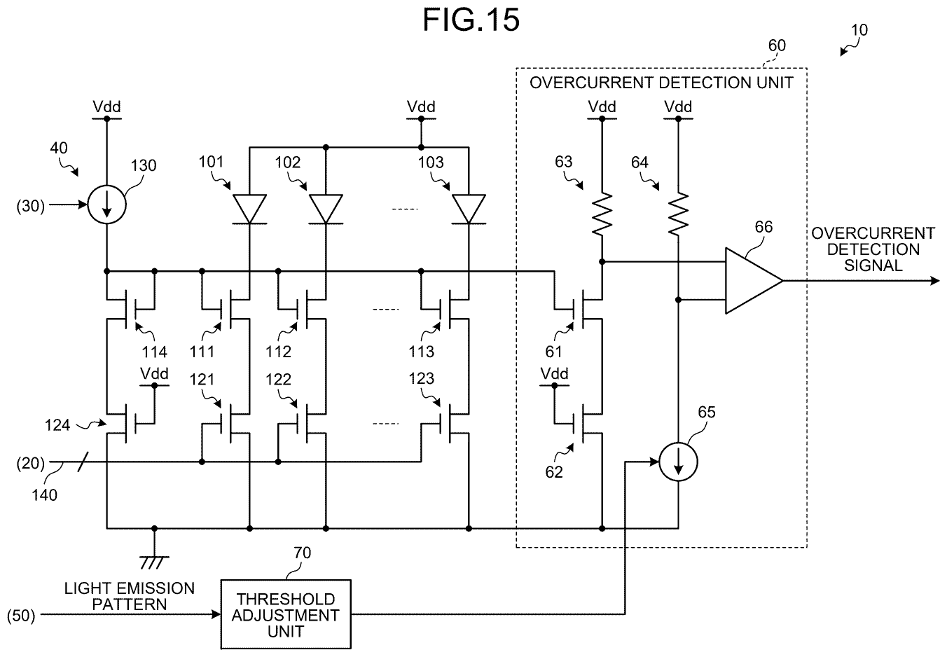

FIG. 15 is a view illustrating a configuration example of a light source device according to the fifth embodiment of the present disclosure. Similarly to FIG. 1, the drawing is a view illustrating a configuration example of the light source device 10. The light source device 10 in the drawing is different from the light source device 10 in FIG. 1 in a point of further including an overcurrent detection unit 60 and a threshold adjustment unit 70.

The overcurrent detection unit 60 includes resistors 63 and 64, MOS transistors 61 and 62, a constant current circuit 65, and a comparator 66. As the MOS transistors 61 and 62, n-channel MOS transistors can be used. One end of the resistor 63 is connected to a power supply line Vdd, and the other end is connected to a drain of the MOS transistor 61 and a comparison input of the comparator 66. A source of the MOS transistor 61 is connected to a drain of the MOS transistor 62, and a source of the MOS transistor 62 is grounded. The gate of the MOS transistor 61 is connected to the drain of the MOS transistor 14, and the gate of the MOS transistor 62 is connected to the power supply line Vdd. One end of the resistor 64 is connected to the power supply line Vdd, and the other end is connected to a sink-side terminal of the constant current circuit 65 and a reference input of the comparator 66. The source-side terminal of the constant current circuit 65 is grounded.

The constant current circuit 65 is a circuit that supplies a constant current based on a control signal from the threshold adjustment unit 70. Potential of the sink-side terminal of the constant current circuit 65 is a threshold voltage of overcurrent detection. Furthermore, potential of the drain of the MOS transistor 61 is potential corresponding to the light emission current. The comparator 66 compares a threshold voltage input to the reference input with a voltage corresponding to the light emission current input to the comparison input, detects an overcurrent in a case where the voltage corresponding to the light emission current exceeds the threshold voltage, and outputs a detection signal. In such a manner, the overcurrent detection unit 60 in the drawing indirectly detects an overcurrent of the light emitting element 101 or the like.

The threshold adjustment unit 70 detects the number of light emitting elements of the light emitting elements 101 and the like on the basis of the light emission pattern, and adjusts a threshold. The light emission current adjustment unit 30 described above adjusts the light emission current according to the number of light emitting elements of the light emitting elements 101 and the like. Thus, by arranging the threshold adjustment unit 70 and adjusting the threshold according to the number of light emitting elements of the light emitting elements 101 and the like, it is possible to improve accuracy of the overcurrent detection.

Since the configuration of the light source device 10 other than the above is similar to the configuration of the light source device 10 in the first embodiment of the present disclosure, description thereof will be omitted.

As described above, the light source device 10 of the fifth embodiment of the present disclosure includes the overcurrent detection unit 60, and detects the overcurrent of the light emission current of the light emitting element 101 or the like. In addition, the threshold at the time of the overcurrent detection is adjusted according to the number of light emitting elements of the light emitting elements 101 and the like. As a result, even in a case where the light emission current is adjusted according to the number of light emitting elements, the accuracy of the overcurrent detection can be improved.

### 6. Modification Example

A modification example of a light source device 10 will be described.

### Configuration of a Light Source Device

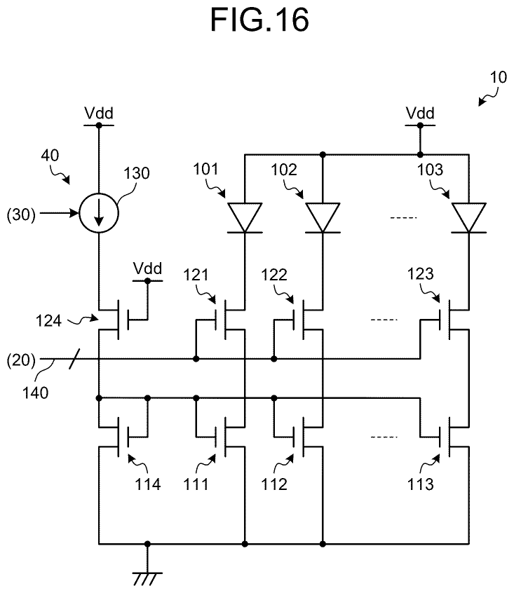

FIG. 16 is a view illustrating a configuration example of a light source device according to a first modification example of the embodiment of the present disclosure. Similarly to FIG. 1, the drawing is a view illustrating a configuration example of the light source device 10. The light source device 10 in the drawing represents an example in which the switch elements 121 to 123 and the current limiting elements 111 to 113 in FIG. 1 are wired with order of connection being switched. In accordance with this, the MOS transistors 114 and 124 are also switched and wired.

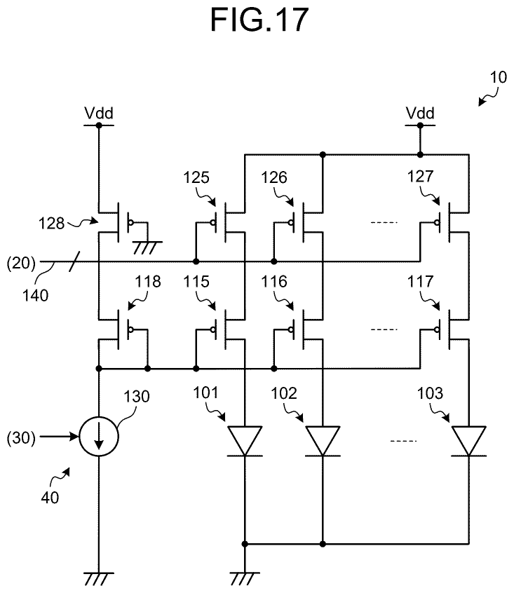

FIG. 17 is a view illustrating a configuration example of a light source device according to a second modification example of the embodiment of the present disclosure. Similarly to FIG. 1, the drawing is a view illustrating a configuration example of a light source device 10. The light source device 10 in the drawing represents an example in a case where switch elements 125 to 127 and current limiting elements 115 to 117 of p-channel MOS transistors are used. Furthermore, p-channel MOS transistors are also used for a MOS transistor 118 of a light emission current control unit 40 and a MOS transistor 128 connected to a source of the MOS transistor 118.

Since the configuration of the light source device 10 other than the above is similar to the configuration of the light source device 10 in the first embodiment of the present disclosure, description thereof will be omitted.

### 7. Configuration of a Light Emitting Element

The configuration of the light emitting element 101 and the like will be described.

### Configuration of a Light Emitting Element

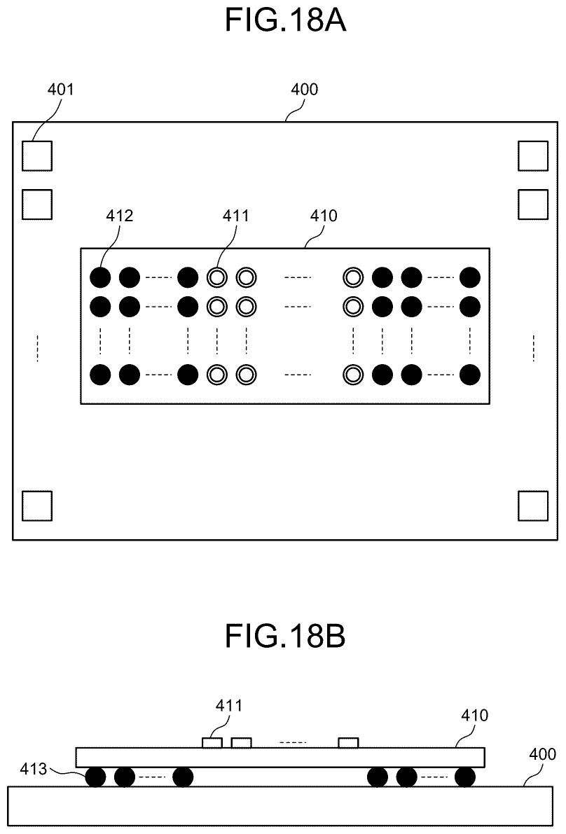

FIG. 18A is a view illustrating a configuration example of a light emitting element according to the embodiment of the present disclosure. The drawing is a view illustrating a configuration example of a light emitting element chip 400 including a light emitting element array 410 in which a plurality of light emitting elements is arranged in an array.

The light emitting element array 410 includes laser diodes 411 as light emitting elements being arranged in a two-dimensional matrix. A vertical cavity surface emitting laser (VCSEL) can be applied to each of the laser diodes 411. Black circles on both sides of the laser diode 411 represent connection terminals 412.

The light emitting element array 410 is mounted on the light emitting element chip 400. Circuits other than the light emitting elements 101 to 103 in FIG. 1 can be arranged on the light emitting element chip 400. Pads 401 are arranged at an end portion of the light emitting element chip 400. The pads 401 and the connection terminals 412 can be connected by bonding wires.

FIG. 18B is a view illustrating another configuration example of a light emitting element according to the embodiment of the present disclosure. This drawing is a view illustrating an example in which a light emitting element array 410 is connected to a light emitting element chip 400 via a bump 413 arranged on a back surface thereof.

### Light Emission Example of a Light Emitting Element

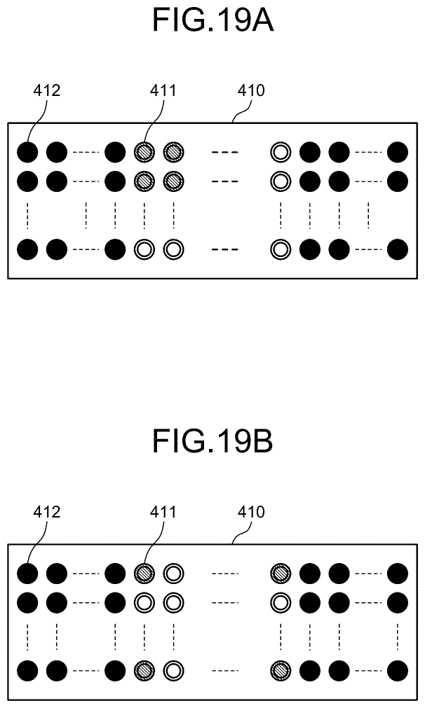

FIGS. 19A to 19B are views illustrating examples of light emission by a light emitting element according to the embodiment of the present disclosure. The drawings are views illustrating an example of light emission of a light emitting element array 410. In the drawings, laser diodes 411 hatched with oblique lines represent laser diodes 411 in a light emitting state.

An example in which adjacent laser diodes 411 are caused to emit light is illustrated in FIG. 19A. In addition, an example in which laser diodes 411 to emit light are dispersed is illustrated in FIG. 19B.

### 8. Application Example to a Distance Measurement Device

### Configuration of a Distance Measurement Device

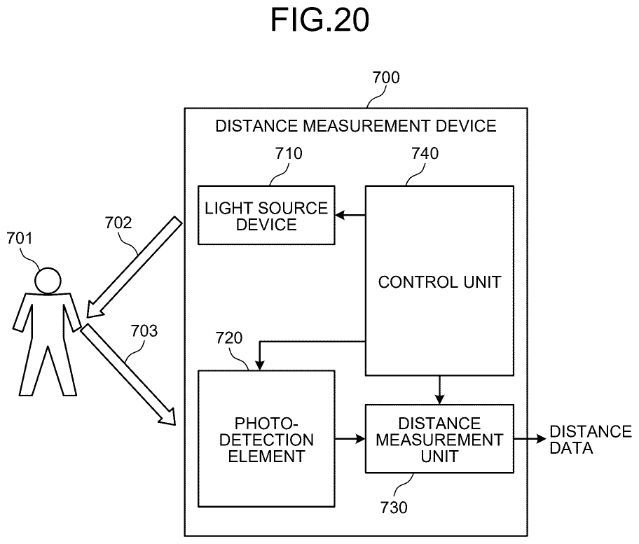

FIG. 20 is a view illustrating a configuration example of a distance measurement device to which a light source device according to an embodiment of the present disclosure can be applied. The drawing is a view illustrating a configuration example of a distance measurement device 700. The distance measurement device 700 is a device that measures a distance to an object. The distance measurement device 700 in the drawing is an example of measuring a distance to an object 701. The distance measurement device 700 includes a light source device 710, a photodetection element 720, a distance measurement unit 730, and a control unit 740. Note that white arrows in the drawing represent light transmission. In the drawing, emission light 702 emitted from the light source device 710 of the distance measurement device 700 is reflected by the object 701 and the reflected light 703 is generated. The reflected light 703 reaches the distance measurement device 700 and is detected by the photodetection element 720. By measuring time (time of flight) from the emission of the emission light 702 to the detection of the reflected light 703, it is possible to measure the distance from the distance measurement device 700 to the object 701.

The light source device 710 emits light to a target of distance measurement. Note that the above-described light source device 10 can be applied to the light source device 710.

The photodetection element 720 includes a plurality of pixels that generates an image signal according to incident light. The photodetection element 720 can include, for example, a complementary metal oxide semiconductor (CMOS) type imaging element. The photodetection element 720 captures an image of the reflected light 703 received in a period synchronized with an emission period and a non-emission period of the emission light 702, and generates an image signal. The photodetection element 720 outputs the generated image signal to the distance measurement unit 730.

The distance measurement unit 730 measures the distance to the object 701. The distance measurement unit 730 measures the distance by measuring the above-described time of flight on the basis of the image signal output from the photodetection element 720. The distance measured by the distance measurement unit 730 is output to the outside of the distance measurement device 700 as distance data.

The control unit 740 controls the entire distance measurement device 700. For example, the control unit 740 instructs the light source device 710 to emit light, and notifies the distance measurement unit 730 of the start of light emission. With this notification, the distance measurement unit 730 starts measuring the time of flight. Furthermore, the control unit 740 performs control such as generation of the image signal on the photodetection element 720. The control unit 740 controls the light source device 710 and the like by outputting a control signal.

Note that the effects described in the present description are merely examples and are not limitations, and there may be another effect.

Note that the present technology can also have the following configurations.
(1) A light source device comprising:
   a plurality of light emitting elements;
   a plurality of switch elements that is respectively connected in series with respect to the plurality of light emitting elements and that causes a light emission current to flow during a light emission period;
   a light emission control unit that controls light emission of the plurality of light emitting elements by controlling the plurality of switch elements;
   a plurality of current limiting elements that is arranged respectively for the plurality of light emitting elements and that limits a current flowing through the light emitting elements to the light emitting current;
   a light emission current control unit that supplies a current control signal corresponding to the light emission current to control terminals of the plurality of current limiting elements; and
   a light emission current adjustment unit that adjusts the light emission current according to the number of light emitting elements caused to emit light among the plurality of light emitting elements.
(2) The light source device according to the above (1), wherein the light emission current adjustment unit adjusts the light emission by adjusting a value of the light emission current in the light emission current control unit.
(3) The light source device according to the above (2), wherein
   each of the current limiting elements includes a MOS transistor having a gate as the control terminal,
   the light emission current control unit includes a MOS transistor included in a current mirror circuit with the plurality of current limiting elements, and supplies a gate voltage of the MOS transistor as the current control signal to the plurality of current limiting elements, and
   the light emission current adjustment unit adjusts the value of the light emission current by adjusting a reference current of the current mirror circuit in the light emission current control unit.
(4) The light source device according to the above (1), wherein the light emission current adjustment unit adjusts the light emission current by adjusting a light emission period in the light emission control unit.
(5) The light source device according to any one of the above (1) to (4), wherein the plurality of light emitting elements is divided into a plurality of regions and arranged.
(6) The light source device according to the above (5), wherein the light emission current adjustment unit adjusts the light emission current for each of the plurality of regions.
(7) The light source device according to any one of the above (1) to (6), further comprising:
   an overcurrent detection unit that detects an overcurrent of the light emission current on a basis of a predetermined threshold; and
   a threshold adjustment unit that adjusts the threshold according to the number of light emitting elements.
(8) A distance measurement device comprising:
   a light source device including
   a plurality of light emitting elements,
   a plurality of switch elements that is respectively connected in series with respect to the plurality of light emitting elements and that causes a light emission current to flow during a light emission period,
   a light emission control unit that controls light emission of the plurality of light emitting elements by controlling the plurality of switch elements,
   a plurality of current limiting elements that is respectively arranged for the plurality of light emitting elements and limits a current flowing through the light emitting elements to the light emission current,
   a light emission current control unit that supplies a current control signal corresponding to the light emission current to control terminals of the plurality of current limiting elements, and
   a light emission current adjustment unit that adjusts the light emission current according to number of light emitting elements caused to emit light among the plurality of light emitting elements;
   a photodetection element that detects reflected light that is light emitted from the light source device and reflected by an object; and
   a distance measurement unit that measures a distance to the object by measuring time from emission of the light to detection of the reflected light.

### REFERENCE SIGNS LIST

10 LIGHT SOURCE DEVICE
20 LIGHT EMISSION CONTROL UNIT
30 LIGHT EMISSION CURRENT ADJUSTMENT UNIT
40 LIGHT EMISSION CURRENT CONTROL UNIT
60 OVERCURRENT DETECTION UNIT
100, 150 REGION
101 to 103, 151 to 153 LIGHT EMITTING ELEMENT
111 to 113, 115 to 117, 161 to 163 CURRENT LIMITING ELEMENT
121 to 123, 125 to 127, 171 to 173 SWITCH ELEMENT
700 DISTANCE MEASUREMENT DEVICE
710 LIGHT SOURCE DEVICE
720 PHOTODETECTION ELEMENT
730 DISTANCE MEASUREMENT UNIT

1. A light source device comprising:
a plurality of light emitting elements;
a plurality of switch elements that is respectively connected in series with respect to the plurality of light emitting elements and that causes a light emission current to flow during a light emission period;
a light emission control unit that controls light emission of the plurality of light emitting elements by controlling the plurality of switch elements;
a plurality of current limiting elements that is arranged respectively for the plurality of light emitting elements and that limits a current flowing through the light emitting elements to the light emitting current;
a light emission current control unit that supplies a current control signal corresponding to the light emission current to control terminals of the plurality of current limiting elements; and
a light emission current adjustment unit that adjusts the light emission current according to the number of light emitting elements caused to emit light among the plurality of light emitting elements.

2. The light source device according to claim 1, wherein the light emission current adjustment unit adjusts the light emission by adjusting a value of the light emission current in the light emission current control unit.

3. The light source device according to claim 2, wherein
each of the current limiting elements includes a MOS transistor having a gate as the control terminal,
the light emission current control unit includes a MOS transistor included in a current mirror circuit with the plurality of current limiting elements, and supplies a gate voltage of the MOS transistor as the current control signal to the plurality of current limiting elements, and
the light emission current adjustment unit adjusts the value of the light emission current by adjusting a reference current of the current mirror circuit in the light emission current control unit.

4. The light source device according to claim 1, wherein the light emission current adjustment unit adjusts the light emission current by adjusting a light emission period in the light emission control unit.

5. The light source device according to claim 1, wherein the plurality of light emitting elements is divided into a plurality of regions and arranged.

6. The light source device according to claim 5, wherein the light emission current adjustment unit adjusts the light emission current for each of the plurality of regions.

7. The light source device according to claim 1, further comprising:
an overcurrent detection unit that detects an overcurrent of the light emission current on a basis of a predetermined threshold; and
a threshold adjustment unit that adjusts the threshold according to the number of light emitting elements.

8. A distance measurement device comprising:
a light source device including
a plurality of light emitting elements,
a plurality of switch elements that is respectively connected in series with respect to the plurality of light emitting elements and that causes a light emission current to flow during a light emission period,
a light emission control unit that controls light emission of the plurality of light emitting elements by controlling the plurality of switch elements,
a plurality of current limiting elements that is respectively arranged for the plurality of light emitting elements and limits a current flowing through the light emitting elements to the light emission current,
a light emission current control unit that supplies a current control signal corresponding to the light emission current to control terminals of the plurality of current limiting elements, and
a light emission current adjustment unit that adjusts the light emission current according to number of light emitting elements caused to emit light among the plurality of light emitting elements;
a photodetection element that detects reflected light that is light emitted from the light source device and reflected by an object; and
a distance measurement unit that measures a distance to the object by measuring time from emission of the light to detection of the reflected light.
